(19) United States
(12) Patent Application Publication
(10) Pub. No.: US 2023/0417697 A1
(43) Pub. Date: Dec. 28, 2023

(54) Capacitive Sensor Device

(71) Applicant: TE Connectivity Sensors France, Toulouse (FR)

(72) Inventors: Francois-Xavier Villemin, Toulouse (FR); Loic Mathieu, Toulouse (FR); Nicolas Bigou, Toulouse (FR); Florent Gaunard, Toulouse (FR)

(73) Assignee: TE Connectivity Sensors France, Toulouse (FR)

(21) Appl. No.: 18/338,533

(22) Filed: Jun. 21, 2023

(30) Foreign Application Priority Data
Jun. 23, 2022 (EP) 22305908.0

(51) Int. Cl. G01N 27/22

(52) U.S. Cl. CPC G01N 27/226

(57) ABSTRACT

A capacitive sensor device includes a printed circuit board (PCB) having a plurality of first vias and a plurality of first tracks connected with the first vias, a sensing device connected with the first vias, and a compensation device. The compensation device reduces a time-dependent parasitic capacity of the PCB between the first vias and/or between the first tracks.

### CROSS-REFERENCE TO RELATED APPLICATIONS

This application claims the benefit of the filing date under 35 U.S.C. § 119(a)-(d) of European Patent Application No. 22305908.0, filed on Jun. 23, 2022.

### FIELD OF THE INVENTION

The present invention relates to a capacitive sensor device for sensing a measurand, for example, properties of a fluid, and, in particular, a capacitive sensor device providing accurate measurements that are not significantly affected by temperature or humidity dependent parasitic capacities.

### BACKGROUND

Sensors are of growing importance and become more and more ubiquitous in every-day life. Microelectromechanical systems (MEMS) are an attractive option to answer the demand for increased performances of sensors along with decreased sizes and costs. For example, temperature sensors, pressure sensors and humidity sensors or a combination thereof as well as sensors for detecting properties of fluids, for example, the viscosity, density or dielectric constant of oil, are known to be used in a large variety of applications.

Capacitive sensor devices represent a class of sensors that allow for relatively accurate measurements. For example, in the art, a humidity sensor device is known that comprises a dielectric substrate, two electrodes formed on the dielectric substrate and a sensitive layer for absorption and/or adsorption of water. A variation of capacitance caused by the absorption and/or adsorption of water can be measured and used for the determination of the (relative) humidity of an environment under the assumption that the water amount detected by the sensor is in thermal equilibrium with the gaseous fraction of water in the environment. Other capacitive sensor devices are configured for sensing measurands such as temperature, pressure or properties of fluids, in general.

Usually, sensing elements of capacitive sensor devices are connected to printed circuit boards (PCBs) carrying or connected with analysis circuitries configured for receiving and processing input data provided by the sensing elements. Such PCBs provide parasitic capacities that may affect the accuracy of measurements made by the capacitive sensor devices. Constant parasitic capacities could be relatively easily compensated for by appropriate calibration of the capacitive sensor devices. However, in actual applications, the parasitic capacities of the PCBs depend on the temperature and/or humidity of the measurement environment. Such time-dependent parasitic capacities may disadvantageously affect measurements in some unpredictable manner and, in particular, in the context of low-capacitance measurements within or below the pico-Farad range, may lead to wrong measurement results.

In view of the above, it is an object of the present invention to provide a capacitive sensor device that allows for a reliable sensing operation that is not significantly affected by a time-dependent parasitic capacity of the PCB comprised in the capacitive sensor device.

### SUMMARY

A capacitive sensor device includes a printed circuit board (PCB) having a plurality of first vias and a plurality of first tracks connected with the first vias, a sensing device connected with the first vias, and a compensation device. The compensation device reduces a time-dependent parasitic capacity of the PCB between the first vias and/or between the first tracks.

### BRIEF DESCRIPTION OF THE DRAWINGS

Exemplary embodiments of the invention are described by way of the following drawings. In the drawings:

FIG. 1 is a schematic diagram of parasitic capacitance provided by a PCB of a capacitive sensor device;

FIG. 2 is a schematic diagram of a capacitive sensor device comprising a compensation device according to an embodiment;

FIG. 3 is a top view of a part of a PCB of a capacitive sensor device comprising stitching between sensitive vias according to an embodiment;

FIG. 4 is a top view of a part of a PCB of a capacitive sensor device comprising stitching between sensitive tracks according to an embodiment;

FIG. 5 is a schematic detail view of a capacitive sensor device comprising a compensation device in form of a screening/shielding grid formed in a PCB of the capacitive sensor device according to an embodiment; and

FIG. 6 is a schematic diagram of a capacitive sensor device comprising a compensation device in form of an opening formed between sensitive vias of a PCB of the capacitive sensor device according to an embodiment.

### DETAILED DESCRIPTION OF THE EMBODIMENT(S)

Features and advantages of the present invention will be described with reference to the drawings. In the description, reference is made to the accompanying figures that are meant to illustrate embodiments of the invention. It is understood that such embodiments do not represent the full scope of the invention.

The present invention provides a capacitive sensor device comprising a compensation device for reducing a time-dependent parasitic capacity of a PCB of the capacitive sensor device between sensitive vias and/or tracks of the PCB such that accurateness of measurements made by the capacitive sensor device are not significantly affected by parasitic capacities. The provided configuration can be easily produced by mass production semiconductor manufacturing processes. It can be manufactured at relative compact sizes and low costs.

Herein, the term ‘capacitive sensor device’ covers any device comprising capacitive sensing elements and any device comprising sensitive elements which provide, possibly additional to main sensing data, capacities (wanted or parasitic) that can be used for the measurement of measurands. The PCB may be a multi-layer PCB. It is noted that the PCB may comprise or be connected with a microcontroller, a microprocessor, some application-specific integrated circuit (ASIC) and/or an application-specific standard product (ASSP) used for the analysis of measurement data and control of the operation of the capacitive sensor device.

FIG. 1 illustrates the problem of a time-dependent parasitic capacitance provided by a PCB of a capacitive sensor device which is addressed by the present invention. FIG. 1 shows a capacitive sensor device 1000 comprising a PCB 100. A sensing device (element) 110 is connected with the PCB 100 via contacts 120 soldered to vias formed in the PCB 100. Further, an analysis (sensing) circuitry 130 is connected with the PCB 100. Electric currents flowing through the contacts 120 and vias cause a parasitic capacitance PC between the vias in the PCB 100. This time-dependent parasitic capacitance PC depends on the temperature and humidity of the environment of the capacitive sensor device 1000. The thus resulting time-dependent parasitic capacitance PC affects accurateness of measurements made by the capacitive sensor device 1000. In the following, solutions of this problem in accordance with the present invention are described.

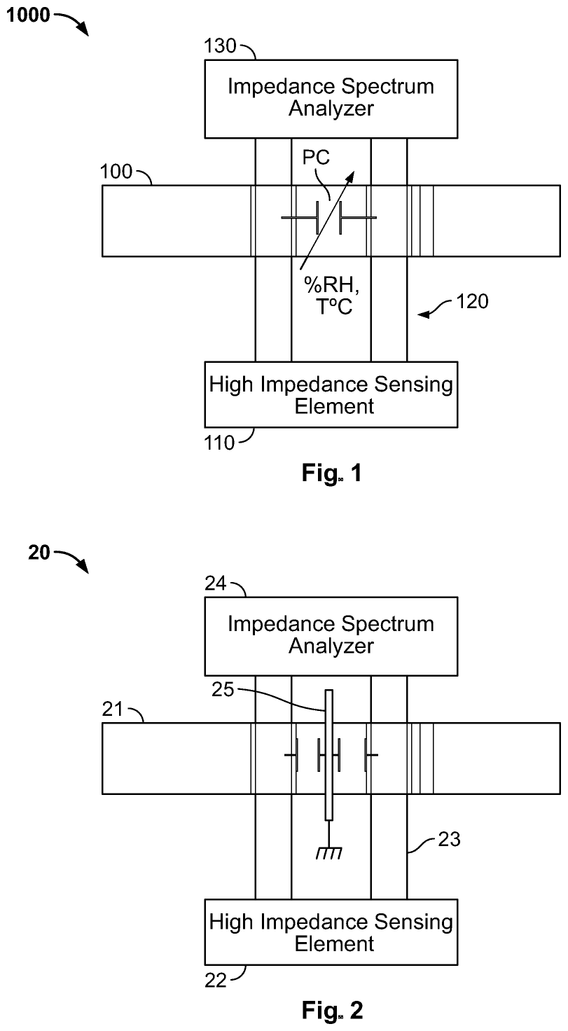

FIG. 2 exemplarily shows an embodiment of a capacitive sensor device 20 according to the invention. The capacitive sensor device 20 comprises a PCB 21, for example, a multi-layer PCB 21. A sensing device (element) 22 is connected with the PCB 21 by contacts 23 soldered to first vias formed in the PCB 21 that are connected with a sensing device (not shown in FIG. 2). A measurand of a medium is sensed by the sensing device 22. Further, an analysis (sensing) circuitry 24 is connected with the PCB 21.

The capacitive sensor device 20, additionally, comprises a compensation device configured for reducing a time-dependent parasitic capacity of the PCB 21 between the first vias in the PCB 21. In the configuration shown in FIG. 2, the compensation device has second vias 25 formed in the PCB 21 between the first vias. The second vias 25 are connected to ground (or another source of a constant electrical potential).

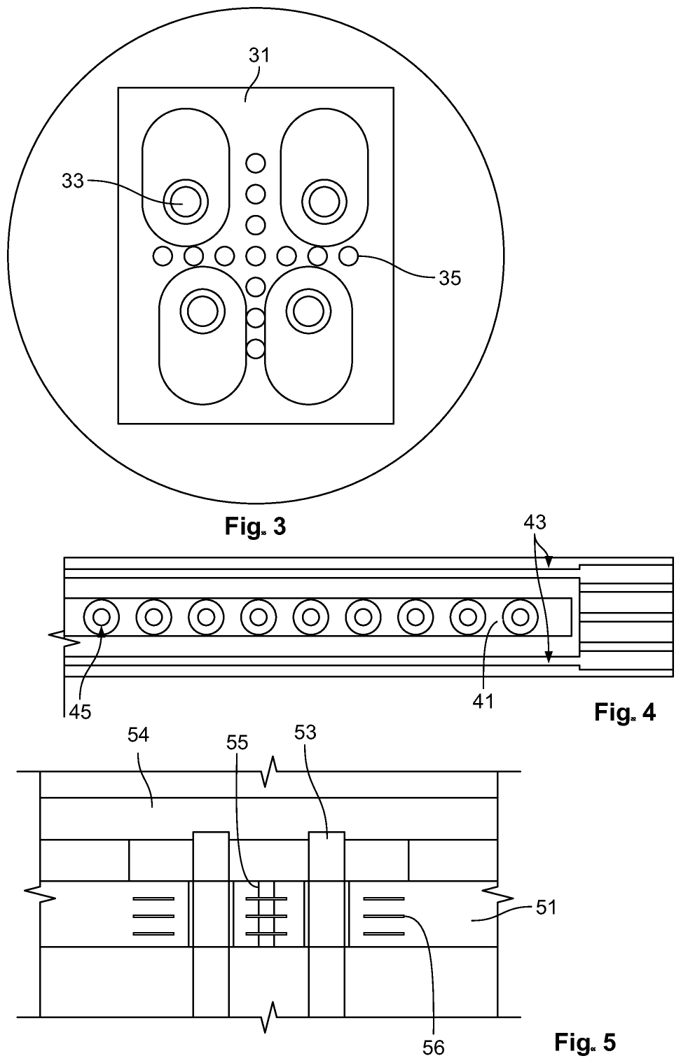

FIG. 3 is a top view of a configuration similar to the one shown in FIG. 2. First vias 33 are formed in a PCB 31. Second vias 35 similar to the second via 25 shown in FIG. 2 are formed in a region of the PCB 31 between the first vias 33. The second vias 35 represent a stitching of the region of the PCB 31 between the first vias 33. By this stitching, the region of the PCB 31 between the first vias 33 is divided into smaller parts which results in a reduction of the overall time-dependent parasitic capacity of the PCB 21 in that region. Similarly, stitching can be provided between sensitive tracks as it is illustrated in FIG. 4.

FIG. 4 is a top view of a configuration comprising tracks (traces) 43 formed on a layer of a multi-layer PCB 41. The tracks 43 are connected with vias (for example, such as the first vias 33 shown in FIG. 3) that in course are connected with a sensing device. The layer can be a top layer or some intermediate layer of the multilayer PCB 41. The stitching is realized by (second) vias 45.

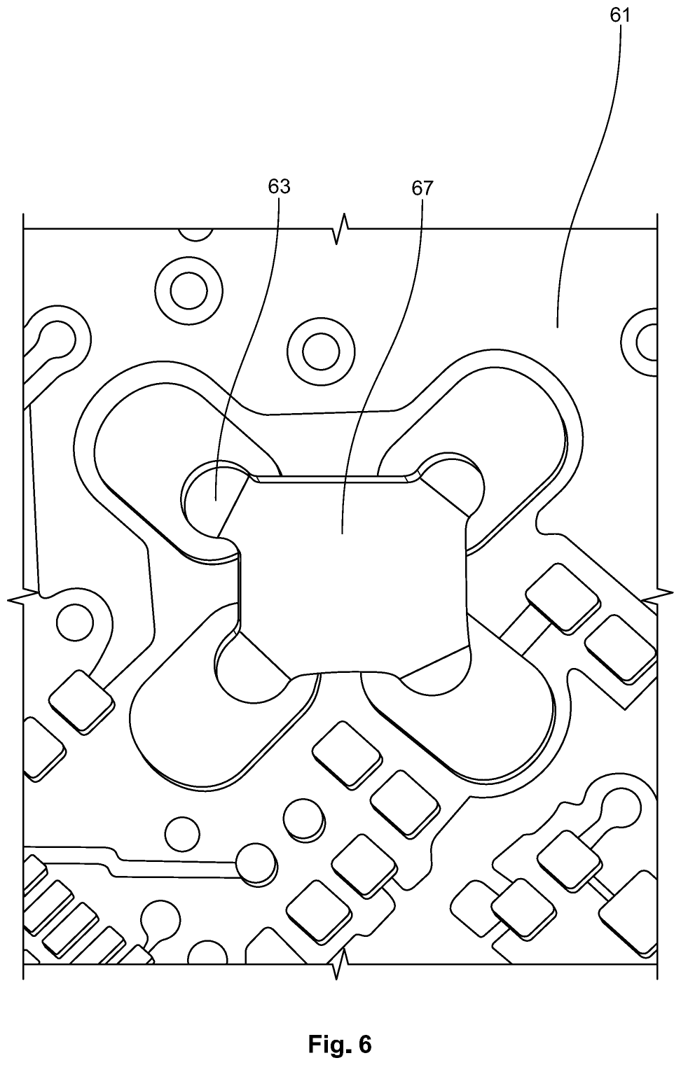

The configurations shown in FIGS. 2, 3 and 4, furthermore, comprise additional (second) tracks connected with the second vias 35, 45. For example, FIG. 5 shows a configuration similar to the one shown in FIG. 2. The configuration shown in FIG. 5 comprises a PCB 51. Contacts 53 are connected to corresponding first vias formed in the PCB 51 and extend to an analysis circuitry 54. Between the first vias, second vias 55 are formed. The second vias 55 are connected with (second) tracks 56 that are formed in layers of the multiple-layer PCB 51. Further, the second vias 55 are connected to ground (see also FIG. 2). The second vias 55 connected to ground and the (second) tracks 56 form a screening/shielding grid that protects sensitive first vias 33 and first tracks 43 (see FIGS. 3 and 4) against fluctuating parasitic capacitances. The first vias and first tracks connected with the sensing device are crucial for a sensing operation of the capacitive sensor device.

By connection with the source of a constant electrical potential, a well-defined capacity is provided that does not affect the measurements. The sensitive first vias and/or first tracks are screened/shielded against perturbations by the constant potential grid provided by the second vias and second tracks. In fact, a capacitance is provided between the grid and the first vias and/or first tracks but no voltage variation between the connections of the sensitive elements that would cause a time-dependent parasitic capacitance. By adding the biased (for example, grounded) grid made of second vias and second tracks, a separation (division) of electric field lines that otherwise would run from one sensitive element pin to another one is caused and, therefore, the equivalent parasitic capacitances variations that would result from such electric field lines without a compensation device in form of the biased grid can be substantially suppressed.

Experiments have proven that the accurateness of low capacity measurements can be significantly increased by provision of the grid of second vias and tracks. The grid of second vias and tracks can be easily formed by an appropriate masking during the production of the PCB. As compared to conventional PCBs used for sensor devices of the art, additional vias and tracks have to be formed which can be easily done at low costs in the context of mass production.

An alternative embodiment of the inventive capacitive sensor device provided herein is illustrated in FIG. 6. Vias 63 (similar to the vias 33 shown in FIG. 3) are formed in a PCB 61 of the capacitive sensor device. The vias 63 are connected by contacts to a sensing device. An opening 67 is milled into the PCB 61 in a region between the vias 63. It is noted that, by the milling process, the portions of the barrels of the vias 63 extending from the board for contacting are reduced in width. Since the material of the PCB 61 is removed between the vias 63, no parasitic capacity can be provided by that material. Rather, air in the opening represents a parasitic capacitor dielectric. However, the dielectric constant of air, as compared to the dielectric constant of the PCB material (for example, an epoxy material), nearly does not depend on the temperature and humidity of the environment of the capacitive sensor device. Therefore, air between the vias 63 provides for an almost constant parasitic capacitance that can be compensated by appropriate calibration of the capacitive sensor device.

It is noted that high-cost materials, for example, ceramic materials, may be used for the production of the PCB that also have dielectric constants that only slightly depend on temperature and humidity. However, usage of such high-cost materials would disadvantageously significantly increase the overall production costs of the capacitive sensor device. The compensation device in form of openings can be provided at low costs. For example, the openings can be formed by milling.

Providing the same effect, openings like the opening 67 shown in FIG. 6 may also be formed between sensitive tracks, for example, between tracks running in parallel to each other as the tracks 43 shown in FIG. 4.

In the above-described configurations, the PCB may comprise an epoxy material (as a base material). PCBs based on an epoxy material can be provided in mass production at low costs. Any disadvantages resulting from the sensitivity of the dielectric constant of the epoxy material against temperature and humidity can be compensated by the compensation device provided in accordance with the present invention. In particular, the compensation device described above may at least partially be formed in the epoxy material. The first and/or second vias may comprise copper barrels and the first and/or second tracks may be made of copper, for example.

According to the present invention, the capacitive sensor device comprises dedicated a compensation device for reducing a time-dependent parasitic capacity of the PCB in regions between networks of first vias and/or tracks that are sensitive to the impact of a time-dependent parasitic capacity of the PCB such that measurements made by the capacitive sensor device would be significantly affected. Due to the provision of the compensation device the time-dependent parasitic capacity of the PCB can be significantly reduced and, thus, accurateness of capacitive measurements made by the capacitive sensor device can be improved as compared to sensor devices of the art.

The problem of parasitic capacitances of PCBs of capacitive sensor devices is of particular relevance in the context of low capacitance measurements. Thus, the compensation device provided in accordance with the present invention may be particularly advantageous for low capacitance measurement applications. Thus, according to an embodiment, the capacitive sensor device is configured for sensing a capacitance of below one pico Farad (for example, in the femto Farad range).

The raw measurement data is provided by the sensing device of the capacitive sensor device that is electrically connected with the PCB of the capacitive sensor device by the first vias. The sensing device may be configured for contacting a fluid such that the capacitive sensor device can measure the property of that fluid.

According to an embodiment, the sensing device comprises sensing electrodes (for example, interdigitated electrodes) and a sensing layer, the sensing electrodes and the sensing layer forming a capacitor. The sensing device may comprise a substrate over or on which the sensing layer is formed. At least one of the sensing electrodes might be formed over the substrate, in particular, over the sensing layer. An adhesion layer (made of chromium, for example) that insures a stable adhesion of the electrodes to the substrate can also be deployed. The sensing layer, for example, exhibits a capacitance formed between the sensing electrodes that varies depending on the quantity of a measurand (for example, temperature, pressure, humidity, viscosity or dielectric constant/permittivity). The sensing layer may be an organic or inorganic dielectric layer, for example, exhibiting a well-defined adsorption/absorption rate for water, and at least one of the sensing electrodes may be formed on or over the sensing layer. The inorganic dielectric layer can be made of or comprise a nitride material, in particular, Si3N4 or silicon carbide.

The above-described embodiments of a capacitive sensor device may be used for sensing a large variety of measurands including temperature, pressure, relative and absolute humidity, viscosity, dielectric constant, contaminants etc. and combinations thereof. For example, the capacitive sensor device can be a fluid sensor device for sensing properties of a fluid (liquid or gas), for example, oil. Such a capacitive sensor device may be used for sensing the properties (for example, viscosity, density, dielectric constant and/or contaminants) of fuel or a coolant or transmission oil, gearbox oil, engine oil or lubricant oil (for example, used in an aircraft or automobile), or air. For example, the degradation of such oils due to contamination by particles may be determined by such a capacitive sensor device, since contaminants alter the dielectric constant of the oil and thereby sensed capacitances. In automotive applications, the capacitive sensor device may be configured to be connected with a CAN bus for data transmission.

Furthermore, it is provided a method of sensing a property of a fluid by means of a capacitive sensor device according to one of the above-described embodiments, comprising contacting the sensing device of the capacitive sensor device with the fluid. The fluid may be oil or an automotive fluid as fuel or a coolant, etc. and the property may be at least one of density, viscosity, temperature, dielectric constant and contaminants.

All previously discussed embodiments are not intended as limitations but serve as examples illustrating features and advantages of the invention. It is to be understood that some or all of the above described features can also be combined in different ways.

What is claimed is:

1. A capacitive sensor device, comprising:
a printed circuit board (PCB) having a plurality of first vias and a plurality of first tracks connected with the first vias;
a sensing device connected with the first vias; and
a compensation device reducing a time-dependent parasitic capacity of the PCB between the first vias and/or between the first tracks.

2. The capacitive sensor device of claim 1, wherein the compensation device has a plurality of second vias arranged in the PCB between the first vias and/or between the first tracks.

3. The capacitive sensor device of claim 2, wherein the second vias are connected with a source of constant electrical potential.

4. The capacitive sensor device of claim 3, wherein the compensation device has a plurality of second tracks arranged in the PCB and connected with the second vias.

5. The capacitive sensor device of claim 4, wherein the source of constant electrical potential is ground.

6. The capacitive sensor device of claim 1, wherein the compensation device has an opening in the PCB between the first vias and/or between the first tracks.

7. The capacitive sensor device of claim 1, wherein the time-dependent parasitic capacity of the PCB depends on temperature and/or humidity of an environment of the capacitive sensor device.

8. The capacitive sensor device of claim 1, wherein the PCB is an epoxy material.

9. The capacitive sensor device of claim 8, wherein the first vias are formed in the epoxy material and the first tracks are formed in or on the epoxy material.

10. The capacitive sensor device of claim 9, wherein the compensation device is at least partially formed in the epoxy material.

11. The capacitive sensor device of claim 1, wherein the capacitive sensor device senses a capacitance of below one pico-Farad.

12. The capacitive sensor device of claim 1, wherein the sensing device contacts a fluid.

13. The capacitive sensor device of claim 1, wherein the sensing device has a plurality of sensing electrodes and a sensing layer, the sensing electrodes and the sensing layer form a capacitor.

14. The capacitive sensor device of claim 1, wherein the capacitive sensor device senses temperature, pressure, relative or absolute humidity, or a combination thereof.

15. The capacitive sensor device of claim 1, wherein the capacitive sensor device senses a property of a fluid.

16. A method of sensing a property of a fluid, comprising:
providing a capacitive sensor device including a printed circuit board (PCB) having a plurality of first vias and a plurality of first tracks connected with the first vias, a sensing device connected with the first vias, and a compensation device reducing a time-dependent parasitic capacity of the PCB between the first vias and/or between the first tracks; and
contacting the fluid with the sensing device of the capacitive sensor device.

17. The method of claim 16, wherein the fluid is an automotive fluid, fuel, a coolant or oil.

18. The method of claim 16, wherein the capacitive sensor device senses a property of the fluid, the property is at least one of viscosity, density, temperature, a dielectric constant and contaminants.
